(19) United States
(12) Patent Application Publication
(10) Pub. No.: US 2014/0159116 A1
(43) Pub. Date: Jun. 12, 2014

(54) III-Nitride Device Having an Enhanced Field Plate

(71) Applicant: International Rectifier Corporation, El Segundo, CA (US)

(72) Inventors: Michael A. Briere, Scottsdale, AZ (US); Jin Wook Chung, Los Angeles, CA (US)

(73) Assignee: International Rectifier Corporation, El Segundo, CA (US)

(21) Appl. No.: 14/085,037

(22) Filed: Nov. 20, 2013

Related U.S. Application Data
(60) Provisional application No. 61/734,488, filed on Dec. 7, 2012.

(51) Int. Cl. H01L 29/778

(52) U.S. Cl. CPC H01L 29/778
USPC 257/194

(57) ABSTRACT

In an exemplary implementation, a semiconductor device includes a III-nitride heterojunction including a III-nitride barrier layer situated over a III-nitride channel layer to form a conduction channel including a two-dimensional electron gas. The semiconductor device further includes a gate electrode coupled to a field plate. The field plate includes a plurality of steps insulated from the conduction channel by a dielectric body and the III-nitride barrier layer. The dielectric body under each one of the plurality of steps contributes to a breakdown voltage that is at least twice a breakdown voltage of the semiconductor device at each corresponding step. The breakdown voltage can correspond to a breakdown voltage of the dielectric body and the III-nitride barrier layer.

The present application claims the benefit of and priority to U.S. Provisional Patent Application Ser. No. 61/734,488, filed on Dec. 7, 2012 and entitled “Enhanced Field Plate Design.” The disclosure of that provisional application is hereby incorporated fully by reference into the present application. This application also hereby incorporates fully by reference a related United States patent application entitled “III-Nitride Semiconductor Device with Stepped Gate Trench and Process for its Manufacture” Ser. No. 12/008,190 filed Jan. 9, 2008, issued as U.S. Pat. No. 8,338,861, and assigned to the assignee of the present application.

### BACKGROUND

I. Definitions

As used herein, the phrase “group III-V” refers to a compound semiconductor including at least one group III element and at least one group V element. By way of example, a group III-V semiconductor may take the form of a III-Nitride semiconductor. “III-Nitride,” or “III-N,” refers to a compound semiconductor that includes nitrogen and at least one group III element such as aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}, aluminum indium gallium arsenide phosphide nitride (AlₓIn_{y}Ga_{(1-x-y)}AsₐP_{b}N_{(1-a-b)}), for example. III-Nitride also refers generally to any polarity including but not limited to Ga-polar, N-polar, semi-polar, or non-polar crystal orientations. A III-Nitride material may also include either the Wurtzitic, Zincblende, or mixed polytypes, and may include single-crystal, monocrystalline, polycrystalline, or amorphous structures. Gallium nitride or GaN, as used herein, refers to a III-Nitride compound semiconductor wherein the group III element or elements include some or a substantial amount of gallium, but may also include other group III elements in addition to gallium.

II. Background Art

A III-nitride heterojunction semiconductor device can include a III-nitride heterojunction having a III-nitride channel layer of one bandgap and a III-nitride barrier layer of another bandgap formed over the III-nitride channel layer. The composition of the III-nitride channel and barrier layers are selected to cause the formation of a carrier rich region referred to as a two-dimensional electron gas (2DEG) at or near the III-nitride heterojunction. The 2DEG can serve as a conduction channel between a first power electrode (e.g. a source electrode) and a second power electrode (e.g. a drain electrode).

The III-nitride heterojunction semiconductor device can also include a field plate coupled to a gate electrode between the first and second power electrodes to enhance breakdown voltage. The field plate may reduce electric field strength at an edge of the gate electrode so as to spread out electric field concentration more uniformly over the 2DEG. The field plate may also replace a single electric field peak at the edge of the gate electrode with multiple electric field peaks. In some approaches, multiple field plates are utilized and coupled to the gate electrode, but are formed separately over different insulator layers. Utilizing multiple field plates can result in additional and higher magnitude electrical field peaks at respective edges of the multiple field plates.

### SUMMARY

A III-nitride device having an enhanced field plate, substantially as shown in and/or described in connection with at least one of the figures, and as set forth more completely in the claims.

### BRIEF DESCRIPTION OF THE DRAWINGS

FIG. 1A presents a cross-sectional view of a portion of an exemplary semiconductor device, in accordance with one implementation of the present disclosure.

FIG. 1B presents an enhanced cross-sectional view of a portion of an exemplary semiconductor device, in accordance with one implementation of the present disclosure.

FIG. 1C presents an enhanced cross-sectional view of a portion of an exemplary semiconductor device, in accordance with one implementation of the present disclosure.

FIG. 2 presents a cross-sectional view of a portion of an exemplary semiconductor device, in accordance with one implementation of the present disclosure.

FIG. 3 presents a cross-sectional view of a portion of an exemplary semiconductor device, in accordance with one implementation of the present disclosure.

FIG. 4 presents a cross-sectional view of a portion of an exemplary semiconductor device, in accordance with one implementation of the present disclosure.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

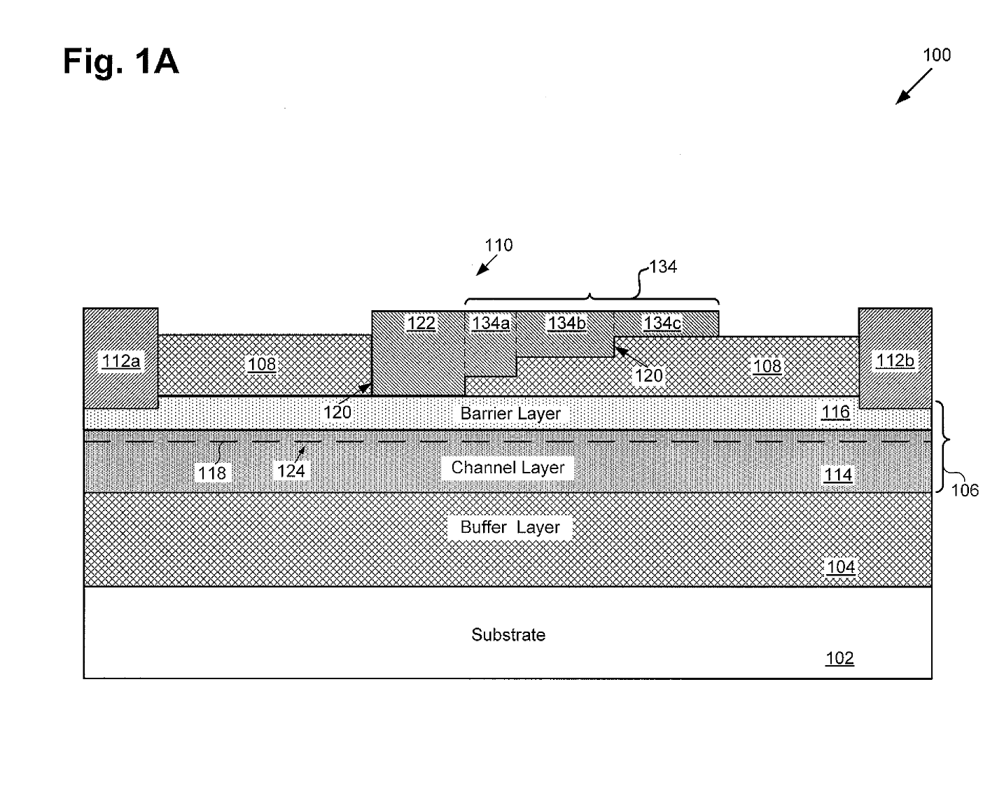

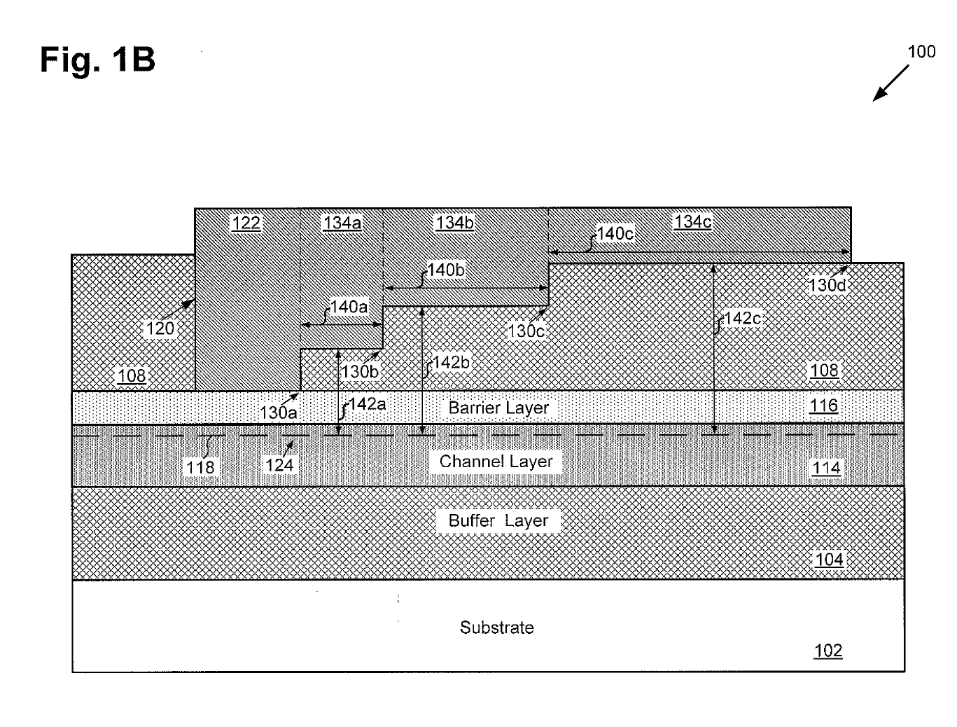

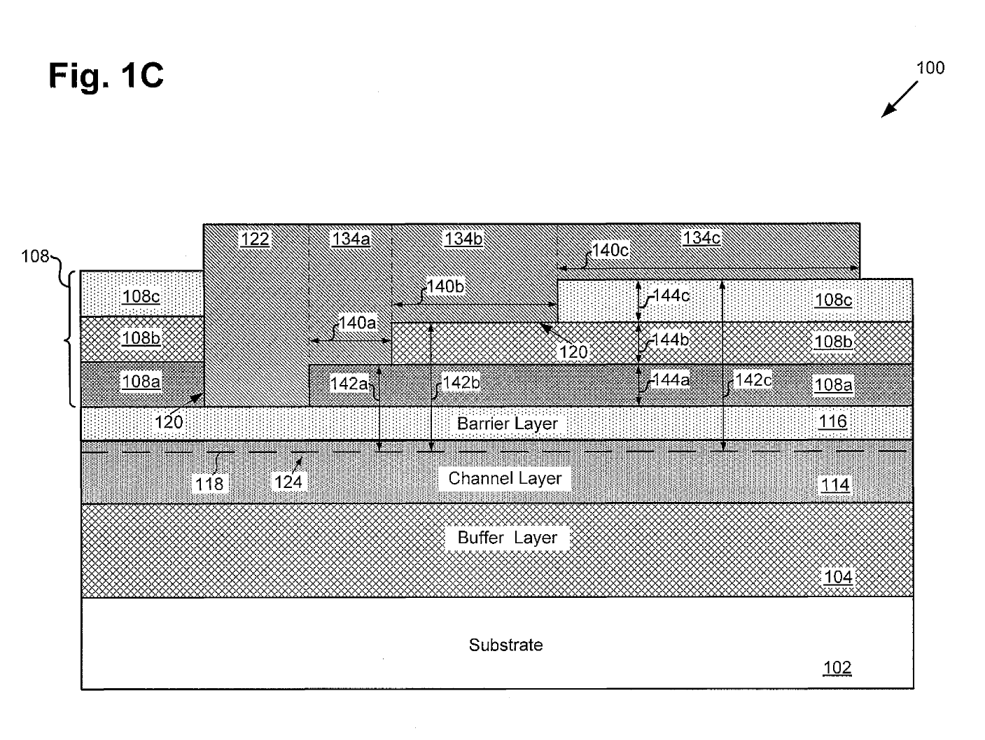

FIG. 1A presents a cross-sectional view of a portion of an exemplary semiconductor device, in accordance with one implementation of the present disclosure. FIGS. 1B and 1C present enhanced cross-sectional views of the portion of the exemplary semiconductor device of FIG. 1A, in accordance with an implementation of the present disclosure. Semiconductor device 100 (e.g. a III-nitride semiconductor device) is a transistor (e.g. a high-electron-mobility transistor). Semiconductor device 100 includes substrate 102, buffer layer 104, III-nitride heterojunction 106, dielectric body 108, gate arrangement 110, and ohmic electrodes 112a and 112b.

In the present implementation, buffer layer 104 includes AlN, by way of example, and is formed over substrate 102. Substrate 102 is a silicon substrate in the present implementation, however other substrate materials can be utilized, for example other group IV materials and silicon on insulator substrates. Semiconductor device 100 can include other layers not specifically shown in FIG. 1A, such as compositionally graded transition layers, strain-relieving interlayers, and amorphous silicon nitride layers amongst others configured to manage stress between substrate 102 and III-nitride layer 114. Other examples include spacer layers and cap layers.

III-nitride heterojunction 106 is formed over buffer layer 104 and includes III-nitride layer 116 situated over III-nitride layer 114 to form conduction channel 124 including two-dimensional electron gas (2DEG) 118. III-nitride layer 114 may also be referred to as a channel layer and III-nitride layer 116 may also be referred to as a barrier layer, as shown in FIG. 1A. The composition of III-nitride layers 114 and 116 are selected to cause formation 2DEG 118, which is rich in carriers and forms conduction channel 124 between ohmic electrodes 112a and 112b. III-nitride layer 114 includes semiconductor material of one bandgap, and III-nitride layer 116 includes semiconductor material of another bandgap. In the present implementation, III-nitride layer 114 includes GaN and III-nitride layer 116 includes AlGaN. However, other semiconductor materials may be utilized, such as other group III-V semiconductor materials (e.g. III-Nitride materials). Furthermore, III-nitride heterojunction 106 can include other layers, such as a spacer layer.

Also in FIG. 1A, ohmic electrodes 112a and 112b are ohmically coupled to III-nitride layer 116 and are thereby electrically coupled to conduction channel 124. Ohmic electrodes 112a and 112b are optionally situated in respective trenches in dielectric body 108 and recessed into III-nitride layer 116. However, in some embodiments, ohmic electrodes 112a and 112b are not recessed into III-nitride layer 116. Ohmic electrodes 112a and 112b extend through dielectric body 108 to contact III-nitride layer 116. In semiconductor device 100, ohmic electrode 112a is a source electrode and ohmic electrode 112b is a drain electrode.

Also in the present implementation, dielectric body 108 is situated over III-nitride heterojunction 106. FIGS. 1A and 1B show dielectric body 108 as including a single dielectric layer, however, dielectric body 108 can include more than one dielectric layer. For example, FIG. 1C shows dielectric body 108 as including dielectric layers 108a, 108b, and 108c. Dielectric layer 108a can be of a first dielectric material and dielectric layer 108b can be of a second dielectric material different than the first dielectric material. Dielectric layer 108c can be, for example, of the first dielectric material, or can be of a third dielectric material different than the first and second dielectric materials. In some implementations, dielectric body 108 alternates between dielectric layers of the first and second dielectric materials.

Dielectric body 108 is configured to passivate III-nitride layer 116. As such, dielectric body 108 can be referred to as a passivation body. Suitable materials for dielectric body 108 include various dielectric materials, such as oxides, nitrides, and/or oxynitrides. In one implementation, dielectric layer 108a is an oxide and dielectric layer 108b is a nitride. In another implementation, dielectric layer 108a is a nitride and dielectric layer 108b is an oxide. Silicon Oxide (SiO₂) is an example of a material suitable for the oxide and silicon nitride (SiₓN_{y}) is an example of a material suitable for the nitride. As another example, dielectric body 108 can include silicon oxynitride.

Gate well 120 is defined by dielectric body 108 and extends through dielectric body 108 to reach III-nitride layer 116. In the implementation shown in FIG. 1C, gate well 120 is formed in dielectric body 108 and is defined by dielectric layers 108a, 108b, and 108c of dielectric body 108. For example, FIG. 1C shows gate well 120 being of a first length defined by dielectric layer 108a, a second length being defined by dielectric layer 108b, and a third length defined by dielectric layer 108c. Those lengths are defined by respective openings in dielectric layers 108a, 108b, and 108c, but can be made generally in one or more dielectric layers. The second length is greater than the first length, and the third length is greater than the second length, such that gate well 120 expands in length away from III-nitride heterojunction 106. It is noted that dielectric body 108 may include additional dielectric layers, such that any of the openings are in multiple dielectric layers.

In some implementations, gate arrangement 110 includes gate electrode 122 situated in gate well 120 and dielectric body 108. At least some of dielectric body 108 may not be present between gate electrode 122 and ohmic electrode 112a or between gate electrode 122 and ohmic electrode 112b. Gate electrode 122 is disposed between ohmic electrodes 112a and 112b and is configured to selectively modulate conduction channel 124, whereby semiconductor device 100 may be operated as a switch. Gate electrode 122 makes Schottky contact with III-nitride heterojunction 106. However, gate arrangement 110 may include a gate dielectric situated between gate electrode 122 and III-nitride layer 116, such that gate electrode 122 makes capacitive contact with III-nitride heterojunction 106.

In gate arrangement 110, gate electrode 122 is coupled to field plate 134, which is integral to gate electrode 122 in the present implementation. Thus, gate electrode 122 and field plate 134 are of a structurally continuous material, such as metal, metal alloy, and/or polysilicon. Gate electrode 122 and field plate 134 collectively fill gate well 120. Field plate 134 is situated over dielectric body 108 and includes steps 134a, 134b, and 134c insulated from conduction channel 124 by at least dielectric body 108 and III-nitride layer 116. In some implementations, field plate 134 may include at least two steps and in other implementations, field plate 134 includes at least three steps. In the implementation shown in FIG. 1C, each of steps 134a, 134b, and 134c is situated on a respective one of dielectric layers 108a, 108b, and 108c of dielectric body 108. Thus, semiconductor device 100 may include at least three dielectric layers, but in some implementations includes at least two dielectric layers. Field plate 134 can optionally extend out from gate well 120, as shown.

In field plate 134, steps 134a, 134b, and 134c are of a continuous layer of conductive material, which may be the same conductive material utilized for gate electrode 122. More particularly, steps 134a, 134b, and 134c are integrally connected with no discontinuities in the conductive material. Such a configuration can prevent the formation of additional, and potentially higher magnitude electrical field peaks that may be formed at respective edges of steps 134a, 134b, and 134c. The conductive material can include one or more conductive layers.

Field plate 134 is situated between gate electrode 122 and ohmic electrode 112b, which is a drain electrode. Thus, field plate 134 may be referred to as a drain-side field plate. Field plate 134 is configured to reduce electric field strength at edge 130a of gate electrode 122, shown in FIG. 1B, so as to spread out electric field concentration more uniformly over 2DEG 118. Field plate 134 also replaces a single electric field peak at edge 130a of gate electrode 122 with multiple electric field peaks at edges 130a, 130b, 130c, and 130d. Implementations of the present disclosure reduce the risk that the multiple electric field peaks are excessive for reliable device operation.

In semiconductor device 100, dielectric body 108, under each one of steps 134a, 134b, and 134c (and each other step in implementations having more steps than shown), contributes to a breakdown voltage of underlying insulator(s) that is at least twice (and may also be at least three times) a breakdown voltage of semiconductor device 100 at each corresponding step. As such, field plate 134 and the underlying insulator(s) are configured such that electric field peaks along any of steps 134a, 134b, and 134c are significantly less than the breakdown voltage of the underlying insulator(s). Thus, semiconductor device 100 can effectively withstand the electric field peaks and have enhanced robustness and breakdown voltage.

In the present implementation, the breakdown voltage corresponds to a breakdown voltage of at least dielectric body 108 and III-nitride layer 116. In the implementation shown in FIG. 1C, for example, the breakdown voltage corresponds to a breakdown voltage of dielectric layers 108a, 108b, 108c, and III-nitride layer 116. For example, the breakdown voltage of dielectric layer 108a and III-nitride layer 116 is at least twice a breakdown voltage of semiconductor device 100 at step 134a. Similarly, the breakdown voltage of dielectric layers 108a and 108b, and III-nitride layer 116 is at least twice a breakdown voltage of semiconductor device 100 at step 134b. Also, the breakdown voltage of dielectric layers 108a, 108b, and 108c, and III-nitride layer 116 is at least twice a breakdown voltage of semiconductor device 100 at step 134c.

Referring to FIG. 1B, steps 134a, 134b, and 134c have respective length values 140a, 140b, and 140c. Length values 140a, 140b, and 140c exhibit an increase in value corresponding to respective distances of steps 134a, 134b, and 134c from gate electrode 122. Thus, length value 140c is the largest value while length value 140a is the smallest value. Also shown in FIG. 1B, combined thickness values 142a, 142b, and 142c of dielectric body 108 and III-nitride layer 116 situated under each respective one of steps 134a, 134b, and 134c also exhibit an increase in value corresponding to the distance of steps 134a, 134b, and 134c from gate electrode 122. As can be seen in FIG. 1C, the increase in value may be provided through combination of thickness values 144a, 144b, and 144c of dielectric layers 108a, 108b, and 108c respectively.

In semiconductor device 100, step 134a has length value 140a that is greater than combined thickness value 142a. Also, step 134b has length value 140b that is greater than combined thickness value 142b. Similarly, step 134c has length value 140c that is greater than combined thickness value 142c. Thus, each respective step in steps 134a, 134b, and 134c has a length value that is greater than a combined thickness value of dielectric body 108 and III-nitride layer 116 situated under each respective step. Doing so can insure that field plate 134 and the underlying insulator(s) are configured such that electric field peaks along any of steps 134a, 134b, and 134c are significantly less than the breakdown voltage of the underlying insulator(s), especially in implementations where dielectric body 108 includes one or more oxides, nitrides, and/or oxynitrides. Thus, semiconductor device 100 can effectively withstand the electric field peaks and have enhanced robustness and breakdown voltage.

In various implementations, length values 140a, 140b, and 140 are at least twice corresponding ones of combined thickness values 142a, 142b, and 142c. Also, length values 140a, 140b, and 140 may be less than approximately three times corresponding ones of combined thickness values 142a, 142b, and 142c.

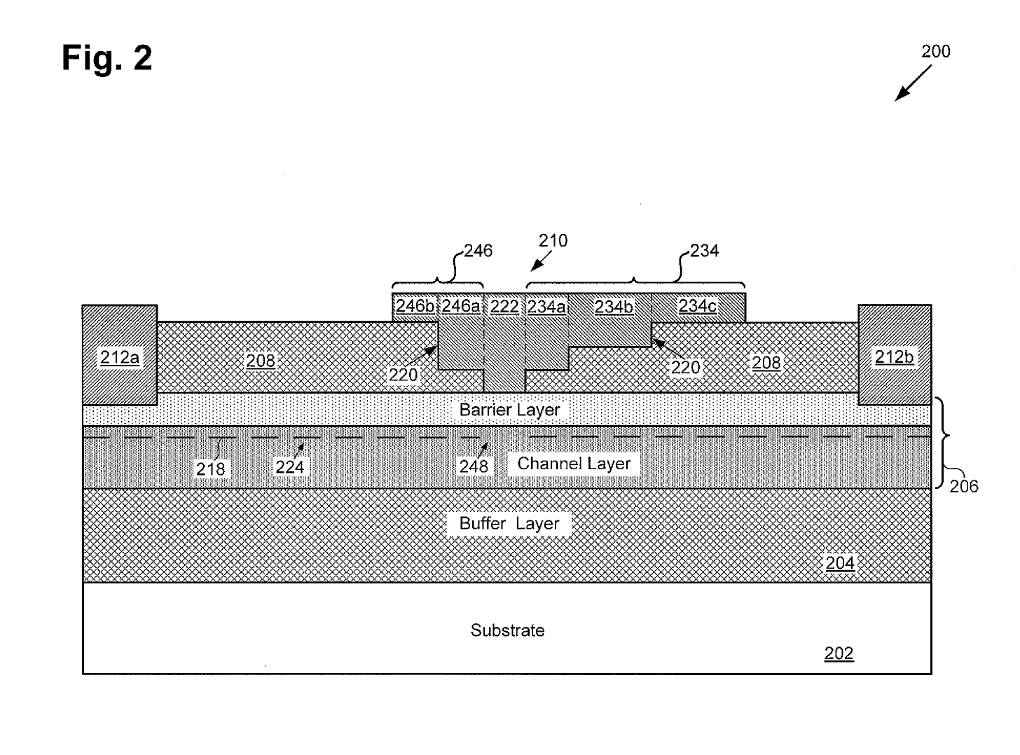

Additional implementations of the present disclosure are described below. Referring now to FIG. 2, FIG. 2 presents a cross-sectional view of a portion of an exemplary semiconductor device, in accordance with one implementation of the present disclosure. In FIG. 2, semiconductor device 200 includes substrate 202, buffer layer 204, III-nitride heterojunction 206, dielectric body 208, gate arrangement 210, and ohmic electrodes 212a and 212b corresponding respectively to substrate 102, buffer layer 104, III-nitride heterojunction 106, dielectric body 108, gate arrangement 110, and ohmic electrodes 112a and 112b in FIGS. 1A, 1B, and 1C.

Semiconductor device 200 is similar to semiconductor device 100, however, in semiconductor device 200, gate arrangement 210 includes field plate 246 in addition to field plate 234. Field plate 246 is situated between gate electrode 222 and ohmic electrode 212a (e.g. a source electrode), and therefore can be referred to as a source-side field plate. Field plate 246 includes one or more steps, but is shown as having steps 246a and 246b. Furthermore, field plate 246 can optionally extend out from gate well 120, as shown.

In semiconductor device 200, field plate 234 is longer than field plate 246, resulting in an asymmetric gate arrangement 210 (i.e. asymmetric across gate electrode 222). This may be accomplished by varying the number and/or length of steps in field plate 246 as compared to field plate 234. For example, in FIG. 2, field plate 234 includes more steps than field plate 246 (e.g. steps 234a, 234b, and 234c compared to steps 246a and 246b).

Also, unlike semiconductor device 100, semiconductor device 200 is an enhancement mode device, as opposed to a depletion mode device. As shown, conduction channel 224 includes interrupted region 248 in 2DEG 218, which is situated under gate electrode 222 absent a bias voltage. Gate electrode 222 can be utilized to restore conductivity to interrupted region 248. Various means are available for rendering semiconductor device 200 enhancement mode, including, but not limited to forming a recess in III-nitride heterojunction 206 under gate electrode 222 or introducing dopants under gate electrode 222. It is noted that any of the implementations described herein may be depletion or enhancement mode devices.

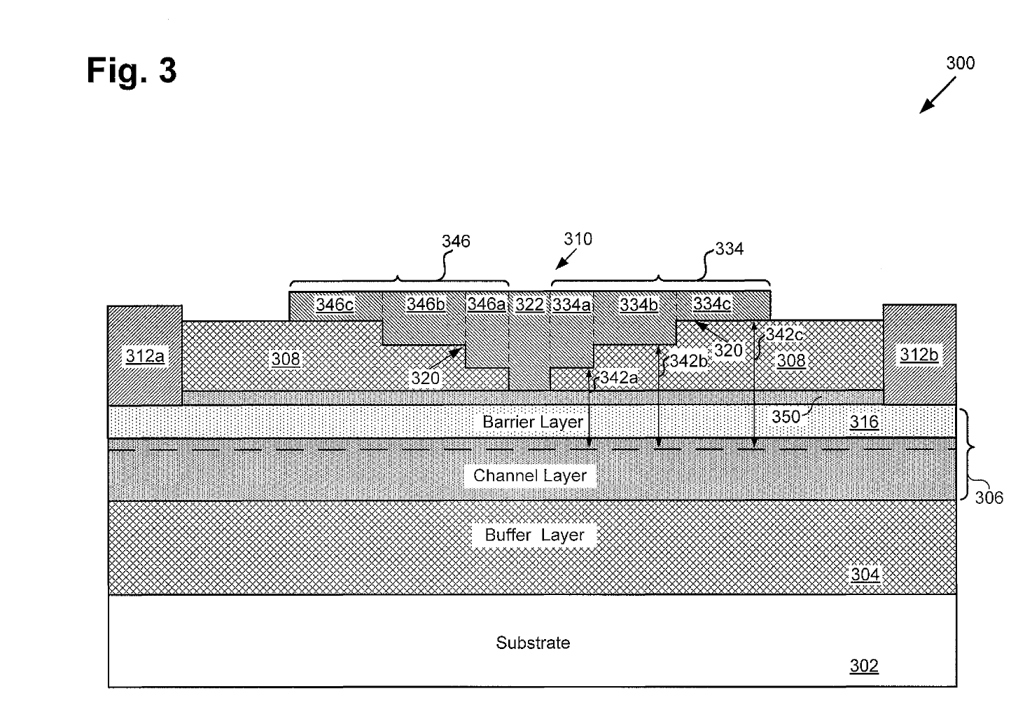

Referring now to FIG. 3, FIG. 3 presents a cross-sectional view of a portion of an exemplary semiconductor device, in accordance with one implementation of the present disclosure. In FIG. 3, semiconductor device 300 includes substrate 302, buffer layer 304, III-nitride heterojunction 306, dielectric body 308, gate arrangement 310, and ohmic electrodes 312a and 312b corresponding respectively to substrate 202, buffer layer 204, III-nitride heterojunction 206, dielectric body 208, gate arrangement 210, and ohmic electrodes 212a and 212b in FIG. 2.

Semiconductor device 300 is similar to semiconductor device 200, however, in semiconductor device 300, gate arrangement 310 is substantially symmetrical across gate electrode 322. Field plate 346 is situated between gate electrode 322 and ohmic electrode 312a (e.g. a source electrode), and therefore can be referred to as a source-side field plate. Field plate 346 includes one or more steps, but is shown as having steps 346a, 346b, and 346c. Steps 346a, 346b, and 346c correspond to and are of substantially a same length as respective ones of steps 334a, 334b, and 334c of field plate 334. Utilizing a substantially symmetrical gate arrangement 310, implementations of the present disclosure may achieve a bidirectional semiconductor device, as shown (i.e. ohmic electrodes 312a and 312b are interchangeable).

Also, unlike semiconductor device 200, semiconductor device 300 includes gate dielectric 350. Gate dielectric 350 is situated between gate electrode 322 and III-nitride heterojunction 306, such that gate electrode 322 makes capacitive contact with III-nitride heterojunction 306. It is noted that any of the implementations described herein may make capacitive contact with a III-nitride heterojunction or may make Schottky contact. Suitable materials for gate dielectric 350 include silicon nitride (SiₓN_{y}) and/or other suitable gate dielectric material or materials.

As shown, gate dielectric 350 is situated below gate well 320. Gate dielectric 350 is also situated at least partially below field plates 334 and/or 346. As such, gate dielectric 350 contributes to combined thickness values 342a, 342b, and 342c corresponding to combined thickness values 142a, 142b, and 142c in FIGS. 1B and 1C. Thus, each respective step in steps 334a, 334b, and 334c has a length value that is greater than a respective one of combined thickness values 342a, 342b, and 342c situated under each respective step. Furthermore, dielectric body 308 under each one of steps 334a, 334b, and 334c contributes to a breakdown voltage that is at least twice a breakdown voltage of semiconductor device 300 at each corresponding step, where the breakdown voltage corresponds to a breakdown voltage of dielectric body 308, and III-nitride layer 316, and gate dielectric 350.

In other implementations, gate dielectric 350 is situated below gate electrode 322 without extending below field plate 334 and/or 346. In such implementations, gate dielectric 350 is optionally situated in and lines gate well 320.

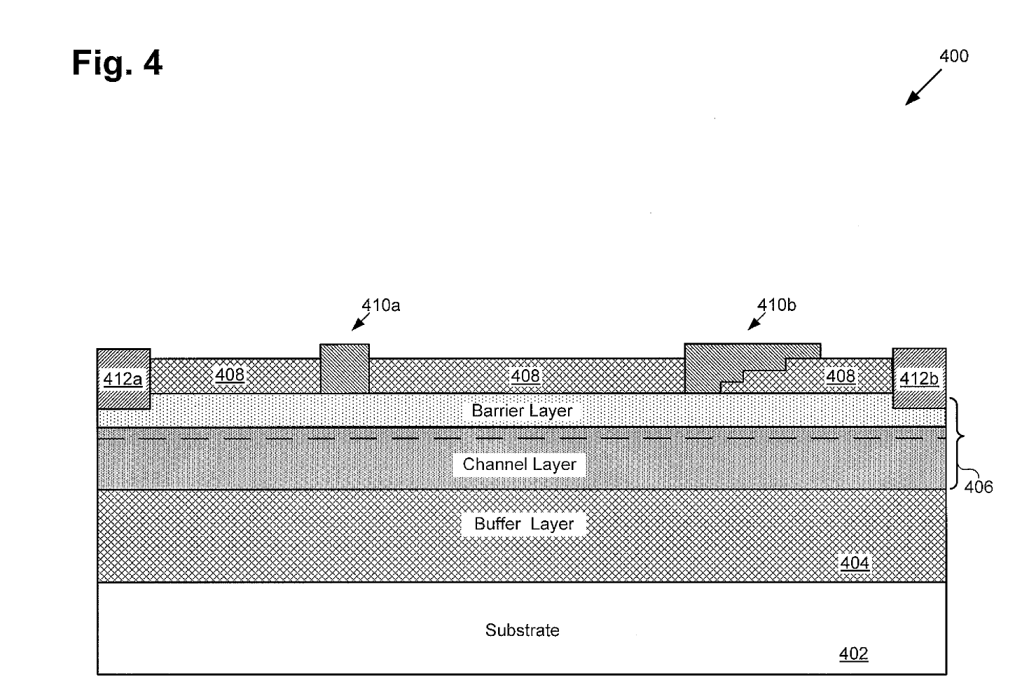

Referring now to FIG. 4, FIG. 4 presents a cross-sectional view of a portion of an exemplary semiconductor device, in accordance with one implementation of the present disclosure. In FIG. 4, semiconductor device 400 includes substrate 402, buffer layer 404, III-nitride heterojunction 406, dielectric body 408, and ohmic electrodes 412a and 412b corresponding respectively to substrate 102, buffer layer 104, III-nitride heterojunction 106, dielectric body 108, and ohmic electrodes 112a and 112b in FIGS. 1A, 1B, and 1C.

Semiconductor device 400 is similar to semiconductor device 100, however, semiconductor device 400 includes more than one gate arrangement. More particularly, semiconductor device 400 is a dual gate semiconductor device and includes gate arrangements 410a and 410b situated between ohmic electrodes 412a and 412b. Gate arrangements 410a and 410b can be controlled separately or may be tied together. Gate arrangement 410a and/or 410b can correspond to gate arrangement 110 of semiconductor device 100 and/or any other gate arrangement disclosed herein. As shown by way of example, gate arrangement 410 is similar to gate arrangement 110 while gate arrangement 410a does not include a field plate. However, gate arrangement 410a may also include a field plate in other implementations. Furthermore, gate arrangement 410b may be provided without a field plate. As shown, gate electrodes in gate arrangements make Schottky contact with III-nitride heterojunction 406. However, at least one of the gate electrodes may make capacitive contact with III-nitride heterojunction 406 (e.g. utilizing a common gate dielectric layer similar to gate dielectric 350 in FIG. 3 or other means).

Thus, as described above with respect to FIGS. 1A, 1B, 1C, 2, 3, and 4 implementations of the present disclosure provide for semiconductor devices having enhanced field plates where electric field peaks along steps of the field plates are significantly less than the breakdown voltage of underlying insulator(s). The, semiconductor devices can thereby effectively withstand the electric field peaks and have enhanced robustness and breakdown voltage.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A semiconductor device comprising:
a III-nitride heterojunction including a III-nitride barrier layer situated over a III-nitride channel layer to form a conduction channel comprising a two-dimensional electron gas;
a gate electrode coupled to a field plate, said field plate comprising a plurality of steps insulated from said conduction channel by a dielectric body and said III-nitride barrier layer;
wherein said dielectric body under each one of said plurality of steps has a breakdown voltage which is at least twice a breakdown voltage of said semicondcutor device at each corresponding step.

2. The semiconductor device of claim 1, wherein said breakdown voltage corresponds to a breakdown voltage of said dielectric body and said III-nitride barrier layer.

3. The semiconductor device of claim 1, wherein said breakdown voltage is at least three times a breakdown voltage of said semiconductor device at each corresponding step.

4. The semiconductor device of claim 1, wherein said field plate is integral to said gate electrode.

5. The semiconductor device of claim 1, wherein said plurality of steps are of a continuous layer of conductive material.

6. The semiconductor device of claim 1, wherein each of said plurality of steps is situated on a respective dielectric layer of said dielectric body.

7. The semiconductor device of claim 1, wherein said plurality of steps comprise at least three steps.

8. The semiconductor device of claim 1, wherein said dielectric body comprises at least three dielectric layers.

9. The semiconductor device of claim 1, wherein said dielectric body comprises silicon nitride.

10. The semiconductor device of claim 1, wherein said dielectric body comprises silicon dioxide.

11. The semiconductor device of claim 1, wherein said dielectric body comprises silicon oxynitride.

12. The semiconductor device of claim 1, wherein said field plate is a drain side field plate and said semiconductor device further comprises a source side field plate, said drain side field plate being longer than said source side field plate.

13. The semiconductor device of claim 1, wherein said field plate is a drain side field plate and said semiconductor device further comprises a source side field plate that is substantially symmetrical to said drain side field plate.

14. A semiconductor device comprising:
a III-nitride heterojunction including a III-nitride barrier layer situated over a III-nitride channel layer to form a conduction channel comprising a two-dimensional electron gas;
a gate electrode coupled to a field plate, said field plate comprising a plurality of steps insulated from said conduction channel by a dielectric body and said III-nitride barrier layer;
wherein each respective step in said plurality of steps has a length value that is greater than a combined thickness value of said dielectric body and said III-nitride barrier layer situated under each said respective step.

15. The semiconductor device of claim 14, wherein said length value is less than approximately three times said combined thickness value.

16. The semiconductor device of claim 14, wherein said length value is at least twice said combined thickness value.

17. The semiconductor device of claim 14, wherein said semiconductor device is a high-electron-mobility transistor.

18. The semiconductor device of claim 14, wherein said gate electrode is in Schottky contact with said III-nitride heterojunction.

19. The semiconductor device of claim 14, comprising a gate dielectric situated between said gate electrode and said III-nitride barrier layer.

20. The semiconductor device of claim 14, wherein said semiconductor device is an enhancement mode device.
